(19) United States
(12) Patent Application Publication
(10) Pub. No.: US 2017/0309584 A1
(43) Pub. Date: Oct. 26, 2017

(54) METHOD OF BONDING A FIRST SUBSTRATE AND A SECOND SUBSTRATE

(71) Applicant: Agency for Science, Technology and Research, Singapore (SG)

(72) Inventors: Ling Xie, Singapore (SG); Sunil Wickramanayaka, Singapore (SG)

(73) Assignees: Agency for Science, Technology and Research, Singapore (SG); Agency for Science, Technology and Research, Singapore (SG)

(21) Appl. No.: 15/518,064

(22) PCT Filed: Oct. 23, 2015
(86) PCT No.: PCT/SG2015/050407

§ 371 Date: Apr. 10, 2017

(30) Foreign Application Priority Data
Oct. 23, 2014 (SG) 10201406863T

(51) Int. Cl. H01L 23/00; H01L 25/065; H01L 25/00

(52) U.S. Cl. CPC H01L 24/13; H01L 24/11; H01L 24/81; H01L 25/0657; H01L 25/50; H01L 24/05; H01L 2224/13611; H01L 2224/13609; H01L 2224/1357; H01L 2224/13565; H01L 2224/13147; H01L 2224/13144; H01L 2224/13124; H01L 2224/13111; H01L 2224/13109; H01L 2224/11464; H01L 2224/05147; H01L 2224/05144; H01L 2224/05124; H01L 2224/05111; H01L 2224/05109; H01L 2224/0401; H01L 2224/1369; H01L 2224/8112; H01L 2224/81825; H01L 2224/81856; H01L 2924/3841; H01L 2225/06513

(57) ABSTRACT

A method for bonding a first substrate and a second substrate, the first substrate having at least one first connection extending from one side of the first substrate, the method comprising fabricating a first adhesive material around and along a height of the at least one first connection; and bonding the at least one first connection, the first adhesive material, and the second substrate.

### PRIORITY CLAIM

This application claims the benefit of priority from Singapore Patent Application No. 10201406863T filed on Oct. 23, 2014, the content of which is incorporated herein by reference in its entirety for all purposes.

### TECHNICAL FIELD

The present invention generally relates to a method for bonding a first substrate and a second substrate (e.g. a semiconductor chip and a semiconductor wafer). More particularly, it relates to a method of two-step bonding using an adhesive material to align and secure the first substrate before carrying out permanent bonding on the first substrate, the adhesive material and the second substrate.

### BACKGROUND ART

In conventional chip-on-wafer (COW) fabrication, a method typically known as flip chip bonding is used. As shown in FIG. 1A, a first substrate 102 (e.g. chip) primarily comprises connections 104a, 104b extending from one side of the substrate 102 and solder caps 106a, 106b fabricated on the vertex (e.g. surfaces facing a second substrate) of the connections 104a, 104b. In other words, the solder caps 106a, 106b are fabricated on the tip of the connections 104a, 104b. As shown in FIG. 1B, the first substrate 102 with connections 104a, 104b (e.g. copper pillars) are aligned and permanently bonded to a second substrate 110 (e.g. a wafer) by heating an assembly 112 (including the first substrate 102 and the second substrate 110) to a solder-melting temperature and using an applied force on the first and second substrate 102, 110. Flip chip bonding is an established one-step process to obtain permanent bonding. However, the use of solder caps 106a, 106b may result in the solder being pressed out when a bonding force is applied on the first and second substrate 102, 110. If the separation between the connections 104a, 104b is small, the solder caps 106a, 106b may transverse the connections 104a, 104b and span across the solder caps 106a, 106b. The span across the solder caps 106a, 106b is typically known as a solder bridge 106c. The solder bridge 106c may cause electrical shortage, and could result in device failure.

Bridging of the solder caps 106a, 106b is typically avoided using a method of solderless bonding. Solder caps 106a, 106b are absent in the first substrate 102 and the second substrate 110 bonded using the method of the solder-less bonding. The first substrate 102 is first brought into alignment with second substrate 110 using a flip chip bonder. The assembly is then transferred to a global chip bonder, where the chips are permanently bonded to the wafer by heating up the assembly and using an applied force. An exemplary technique used to bond the first substrate 102 permanently to the second substrate 110 is diffusion bonding. However, misalignments between the first substrate 102 and the second substrate 110 may occur in the fabrication process, especially during the transfer between different chip bonders. Misalignments may result in defects and circuit open/shortage, which can cause device failure or affect device reliability.

Thus, what is needed is a method of bonding the first substrate and the second substrate that seeks to address some of the above problems. Furthermore, other desirable features and characteristics will become apparent from the subsequent detailed description and the appended claims, taken in conjunction with the accompanying drawings and this background of the disclosure.

### SUMMARY OF INVENTION

An aspect of the present invention provides a method for bonding a first substrate and a second substrate, the first substrate having at least one first connection extending from one side of the first substrate, the method comprising fabricating a first adhesive material around and along a height of the at least one first connection; and bonding the at least one first connection, the first adhesive material, and the second substrate.

### BRIEF DESCRIPTION OF DRAWINGS

The accompanying figures where like reference numerals refer to identical or functionally similar elements throughout the separate views and which together with the detailed description below are incorporated in and form part of the specification, serve to illustrate various embodiments and to explain various principles and advantages in accordance with a present embodiment.

Embodiments of the invention will be better understood and readily apparent to one of ordinary skill in the art from the following written description, by way of example only, and in conjunction with the drawings in which:

FIGS. 1A and 1B show a cross-sectional view of a first substrate and a second substrate being bonded in accordance with a conventional method.

FIG. 2 shows a flowchart illustrating a method of bonding a first substrate and a second substrate in accordance with an embodiment of the present invention.

FIGS. 3A and 3B show cross-sectional diagrams illustrating the first and the second substrates prior to, and after being bonded in accordance with a first embodiment of the present invention.

FIGS. 4A and 4B show cross-sectional diagrams illustrating the first and the second substrates prior to and after being bonded in accordance with a second embodiment of the present invention.

FIGS. 5A and 5B show cross-sectional diagrams illustrating the first and the second substrates prior to and after being bonded in accordance with a third embodiment of the present invention.

FIGS. 6A and 6B show cross-sectional diagrams illustrating the first and the second substrates prior to and after being bonded in accordance with a fourth embodiment of the present invention.

FIGS. 7A to 7C show cross-sectional and plan views of the first and the second substrates in accordance with embodiments of the present invention.

FIG. 8 shows a flowchart illustrating the method for fabricating the first substrate used in the first, second, third and fourth embodiments.

FIGS. 9A to 9W show cross-sectional diagrams illustrating embodiments of the method described in FIG. 8.

FIGS. 10A and 10B show a graphical representation of how viscosity changes with temperature when a first adhesive material is a thermoset polymer and a thermoplastic polymer respectively.

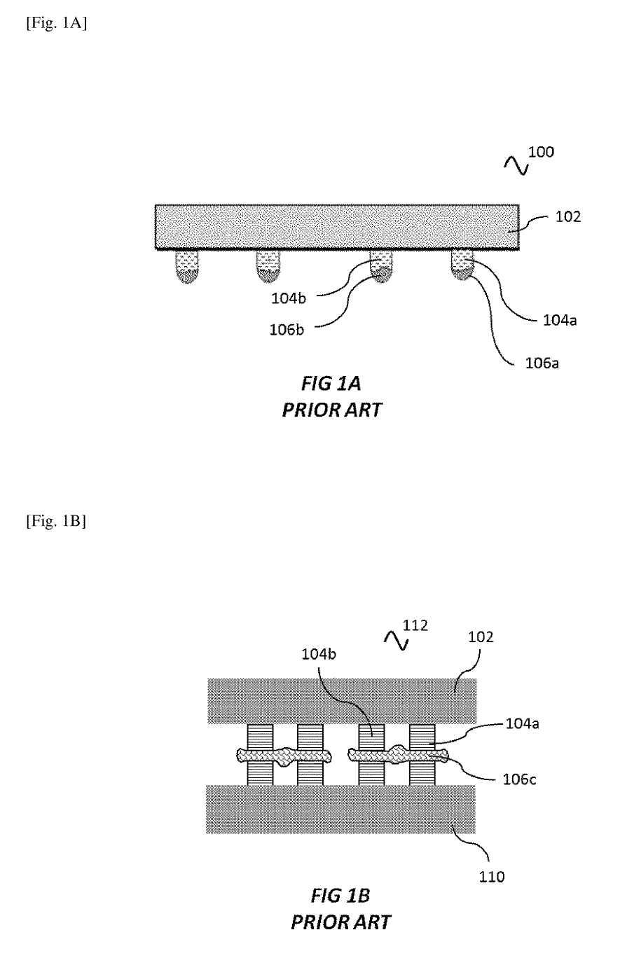

### DESCRIPTION OF EMBODIMENTS

The following detailed description is merely exemplary in nature and is not intended to limit the invention or the application and uses of the invention. Furthermore, there is no intention to be bound by any theory presented in the preceding background of the invention or the following detailed description. Herein, a method for bonding a first substrate and a second substrate is presented in accordance with present embodiments having the advantages of improved alignment, higher mechanical strength, better electrical conductivity, greater device reliability and higher density of connections with fine pitches.

In an embodiment, a substrate may be understood to mean any package comprising semiconductor material, including but not limited to a semiconductor integrated circuit (IC) chip, semiconductor integrated circuit (IC) die or semiconductor wafer.

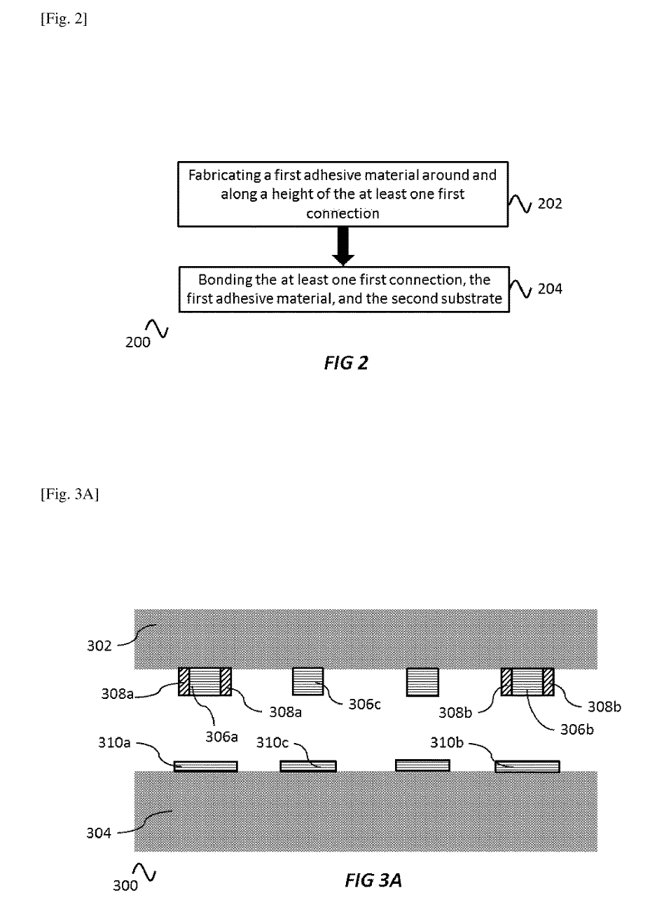

FIG. 2 shows a flowchart 200 illustrating a method of bonding the first substrate and the second substrate in accordance with an embodiment of the present invention.

With reference to FIG. 2, the method for bonding a first substrate having at least one first connection extending from one side of the substrate and a second substrate is illustrated. The method comprises firstly, as described in step 202, fabricating a first adhesive material around and along a height of the at least one first connection and secondly, as described in step 204, bonding the at least one first connection, the first adhesive material and the second substrate. It is obvious to a person skilled in the art that additional steps may be performed before, during and/or after the steps 202 and 204 in various embodiments of the method. The first adhesive material comprises a material selected from a group comprising tin, indium and a polymer material suitable for fabricating around and along the at least one first connection. Examples of polymer materials that are suitable include a thermoset polymer and a thermoplastic polymer.

In an embodiment, the step 204 of bonding the at least one first connection, the first adhesive material, and the second substrate is performed using a flip chip technique. The first substrate is first brought into alignment with the second substrate by a flip chip bonder and pressed together with a bonding force while heating the first and the second substrate to a melting temperature of the first adhesive material when the first adhesive material is a metal. The flip chip bonder is a precision instrument used to align and bond one or more substrates onto another substrate using pressure and/or heat.

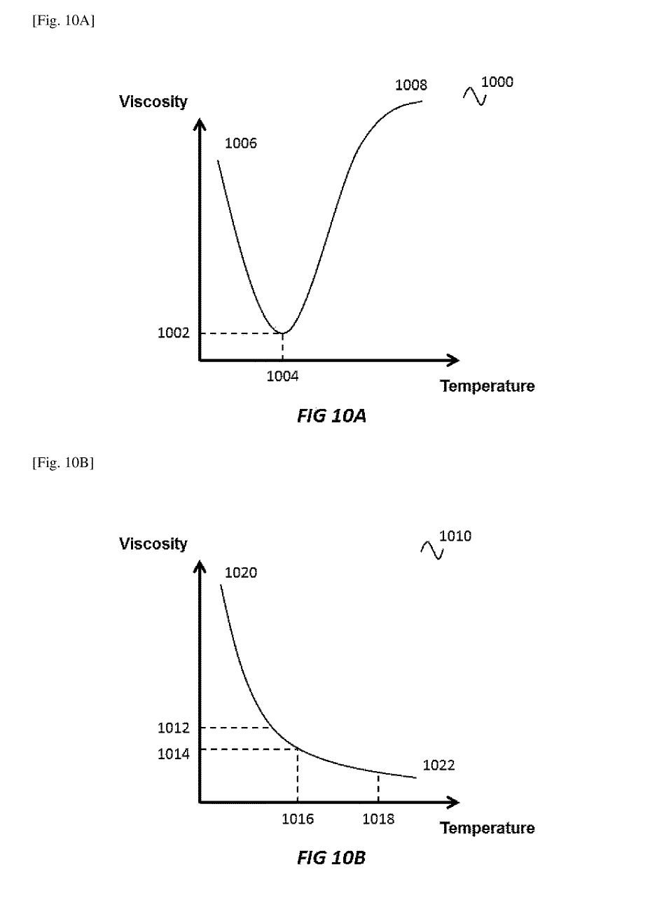

In other embodiments, the first substrate is first brought into alignment with the second substrate by the flip chip bonder and pressed together with a bonding force while heating the first and the second substrate to a predetermined melt-viscosity temperature when the first adhesive material is a polymer. The first adhesive material may comprise a thermoset polymer, or a thermoplastic polymer. An example of the predetermined melt-viscosity temperature of the thermoset polymer is shown in FIG. 10A, while an example of the predetermined melt-viscosity temperature of the thermoplastic polymer is shown in FIG. 10B.

FIG. 10A shows a graphical representation 1000 of how viscosity changes with temperature when the first adhesive material is the thermoset polymer. A thermoset polymer has a viscosity value 1006 when it is in an intermediate reaction stage known as a B-stage by a person skilled in the art. The B-stage is an intermediate reaction stage in the reaction of thermoset polymers, wherein the thermoset polymer softens when heated and is only partially cured. In other words, the thermoset polymer may not entirely fuse. An example of a B-stage thermoset polymer is a resin in an uncured thermosetting system. Curing of the thermoset polymer can be induced by the action of temperature or suitable radiation, or both. As the temperature increases, the thermoset polymer in the viscous state will change irreversibly into an infusible and insoluble material by curing. The viscosity of the thermoset polymer accordingly will first drop to a lowest melt-viscosity value 1002 before increasing to a viscosity value 1008 as the curing process completes. With reference to step 204, the predetermined melt-viscosity temperature when the first adhesive material is the thermoset polymer is shown as a lowest melt-viscosity temperature 1004 after the B-stage. In other words, the lowest melt-viscosity temperature 1004 is one at which the thermoset polymer reaches its lowest viscosity. The lowest melt-viscosity temperature 1004 corresponds to the lowest melt-viscosity 1002 of the thermoset polymer. Therefore, in step 204, the first substrate is first brought into alignment with the second substrate by the flip chip bonder and pressed together with a bonding force while heating the first and the second substrate to a lowest melt-viscosity temperature after the B stage of the first adhesive material when the first adhesive material is the thermoset polymer.

FIG. 10B shows a graphical representation 1010 of how viscosity changes with temperature when the first adhesive material is the thermoplastic polymer. The viscosity of the thermoplastic polymer decreases monotonically with an increase in the temperature. In a low temperature, the thermoplastic polymer will be in a solid state, with a viscosity value 1020. As the temperature increases, the viscosity value of the thermoplastic polymer decreases; at sufficiently high temperatures, the thermoplastic polymer may be in a liquid state with viscosity value 1022. In step 204, the predetermined melt-viscosity temperature when the first adhesive material is the thermoplastic polymer is shown as melt-viscosity temperature 1016, which corresponds to a material viscosity 1014. The predetermined melt-viscosity temperature 1016 is one at which the corresponding material viscosity 1014 is below a predetermined viscosity 1012, while at the same time, below temperature 1018, which corresponds to 200 degree Celsius. In other words, a low melt-viscosity temperature when the first adhesive material is the thermoplastic material is one at which the material viscosity is beyond a predetermined viscosity, and at the same time, below 200 degree Celsius. The predetermined viscosity 1012 may be selected such that in the heating duration of the step 204, the first adhesive material effectually flows and bonds the at least one first connection, the first adhesive material, and the second substrate during the heating duration. Therefore, in step 204, the first substrate is first brought into alignment with the second substrate by the flip chip bonder and pressed together with a bonding force while heating the first and the second substrate to the low melt-viscosity temperature of less than 200 degree Celsius when the first adhesive material is a thermoplastic polymer.

Additionally, the heating duration may be in a range of a few seconds, to effectually prevent the consumption of the first adhesive material caused by diffusion into the at least one first connection. The first and the second substrates are quickly cooled after step 204, and beneficially seals the at least one first connection within the first adhesive material. In embodiments of the present invention, the melting point of the first adhesive material is lower than a melting point or a eutectic point temperature of the at least one first connection material. Advantageously, the step 204 of bonding the at least one first connection, the first adhesive material, and the second substrate reduces chances of misalignments between the first and second substrate during subsequent fabrication processes.

In an embodiment, the step 204 is repeated to bond at least one first substrate (e.g. IC die) to a single second substrate (e.g. semiconductor wafer) using a flip chip technique. Once the at least one first substrate is bonded to the single second substrate, the assembly of the at least one first substrate and the single second substrate are placed in a global wafer bonder, wherein the step 204 of bonding the first connection, the first adhesive material and the single second substrate is performed using a global bonder technique. A bonding force is applied on the at least one first substrate and the single second substrate, and the assembly is heated to the eutectic point temperature of the first connection material. As the first adhesive material softens and deforms, the bonding force is transmitted through the at least one first connection. Bonding between the at least one first connection, the first adhesive material and the second substrate then occurs. Permanent bonds are formed through diffusion bonding between the at least one first connection, the first adhesive material and the second substrate. Advantageously, the use of the proposed method for bonding the first substrate and the second substrate can result in strong bonding between the at least one first connection and the second substrate if similar materials are used. The permanent bond formed has advantage in higher mechanical strength and better electrical conductivity. The permanent bond will have the same coefficient of thermal expansion (CTE) across the at least one first connection and the second substrate, leading to greater device reliability.

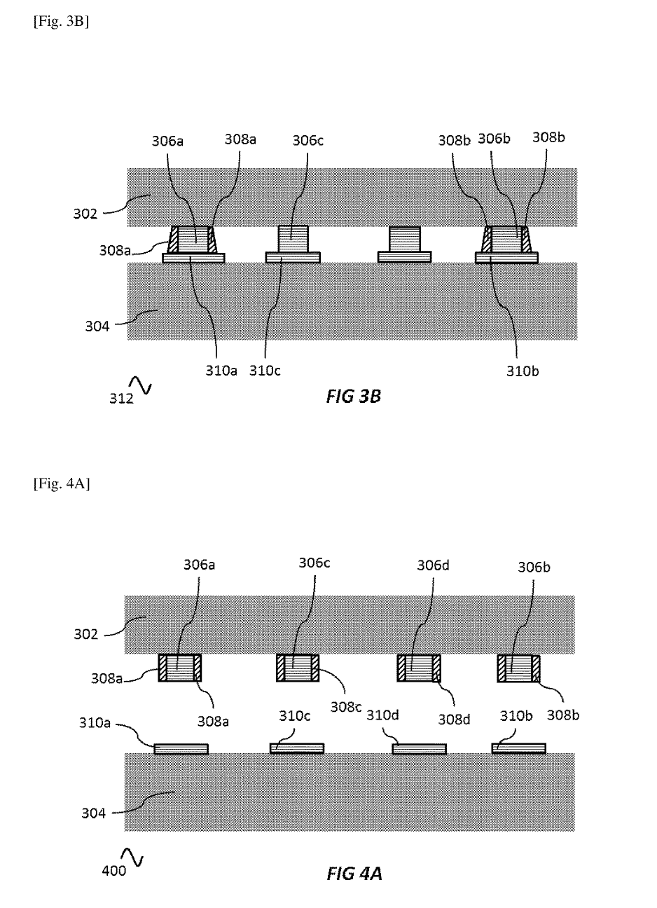

FIGS. 3A and 3B show cross-sectional diagrams illustrating the first and the second substrates prior to, and after being bonded in accordance with a first embodiment of the present invention.

Referring to FIG. 3A, the arrangement 300 shows a first substrate 302, an at least one first connection 306a, 306b extending from one side of the first substrate 302, a first adhesive material 308a, 308b around and along a height of the at least one first connection 306a, 306b respectively and at least one UBM portion 310a, 310b on the second substrate 304 provided below and away from the first substrate 302.

In an embodiment, the first adhesive material 308a is fabricated around and along the at least one first connection 306a in step 202 as described in the above. The first adhesive material 308a may be a cylindrical structure around and along the first connection 306a. In other embodiments, there may be more than one first connection 306a. As shown in FIG. 3A, there are first connections 306a, 306b, 306c extending from the one side of the first substrate 302. The first connections 306a, 306b, 306c may be spaced apart from one another at an equal distance or a different distance. In an embodiment, as shown in FIG. 3A, the first adhesive material 308a, 308b is provided around and along the height of the first connections 306a, 306b that are at the peripheral of the first substrate 302. In other words, the first connections that are located in the centre of the first substrate 302 will not be provided a first adhesive material. One such example is the first connection 306c. Referring to FIG. 3A, the second substrate 304 is provided below and away from the first substrate 302. The at least one under bump metallization (UBM) portion is provided on the second substrate 304. In an embodiment, there are more than one UBM portions. As shown in FIG. 3A, there are UBM portions 310a, 310b, 310c provided on the second substrate 304. In an embodiment, as shown in FIG. 3A, the UBM portions 310a, 310b, 310c are evenly spaced apart on the second substrate 304, wherein centrelines of the UBM portions 310a, 310b, 310c are aligned with centrelines of the corresponding first connections 306a, 306b, 306c on the first substrate 302.

Referring to FIG. 3B, the arrangement 312 shows the first substrate 302, with the at least one first connection 306a, 306b, 306c extending from one side of the first substrate 302 bonded to the at least one UBM portion 310a, 310b, 310c on the second substrate 304 after step 204. In step 204, the first adhesive material 308a, 308b and the first connections 306a, 306b are bonded to the second substrate 304. In an embodiment, the first adhesive material 308a, 308b and the first connections 306a, 306b are first bonded together before subsequently bonded to the second substrate 304. As illustrated in FIG. 3B, the first adhesive material 308a, 308b are shown tapered as the first adhesive material 308a, 308b melts and reflows when the assembly 312 is heated to a melting temperature of the first adhesive material 308a, 308b when the first adhesive material 308a, 308b is a metal. In an embodiment, the first substrate 302 is first brought into alignment with the second substrate 304 by the flip chip bonder and pressed together with a bonding force while heating the first and the second substrate 302, 304 to the lowest melt-viscosity temperature after the B stage of the first adhesive material 308a, 308b when the first adhesive material 308a, 308b is the thermoset polymer. In another embodiment, the first substrate 302 is first brought into alignment with the second substrate 304 by the flip chip bonder and pressed together with a bonding force while heating the first and the second substrate 302, 304 to the low meltviscosity temperature of less than 200 degree Celsius when the first adhesive material 308a, 308b is the thermoplastic polymer. The first adhesive material 308a, 308b may remain straight, as the duration of heating the assembly 312 in step 204 and adhesive thickness of the first adhesive material 308a, 308b can be controlled. Advantageously, with reference to FIGS. 2 and 3, the method for bonding a first substrate and a second substrate as presented avoids the formation of the solder bridge 106c. The method of bonding as presented alleviates concerns on formation of the solder bridge 106c, and facilitates higher density of connections with fine pitches.

In an embodiment, the at least one first connection 306a, 306b, 306c can be fabricated using electrochemical plating. The at least one first connection 306a, 306b, 306c comprises a material selected from a group comprising copper, gold, aluminum, tin and indium. The first adhesive material 308a, 308b can fabricated using an electroless deposition technique (e.g. electroless plating), and the first adhesive thickness is in a range of 100 nm to 2 μm. In other embodiments, the first adhesive thickness may not be limited to the typical range of 100 nm to 2 μm, and can be varied accordingly. As mentioned in the above, the first adhesive material 308a, 308b comprises a material selected from but not limited to a group comprising tin, indium and a polymer material suitable for fabricating around and along the at least one first connection 306a, 306b. The UBM portions 310a, 310b, 310c on the second substrate 304 comprise a material selected from but not limited to a group comprising copper, gold, aluminum, tin and indium and can be fabricated using physical vapour deposition (PVD). Advantageously, the UBM portions 310a, 310b fabricated using PVD has an extremely smooth surface, with surface roughness of around 1 nm. The smooth surface increases area of surface contact during bonding of the first adhesive material 308a, 308b to the corresponding at least one UBM portion. The smooth surface also effectively lowers the bonding force required for bonding the first connections 306a, 306b, 306c to the UBM portions 310a, 310b, 310c.

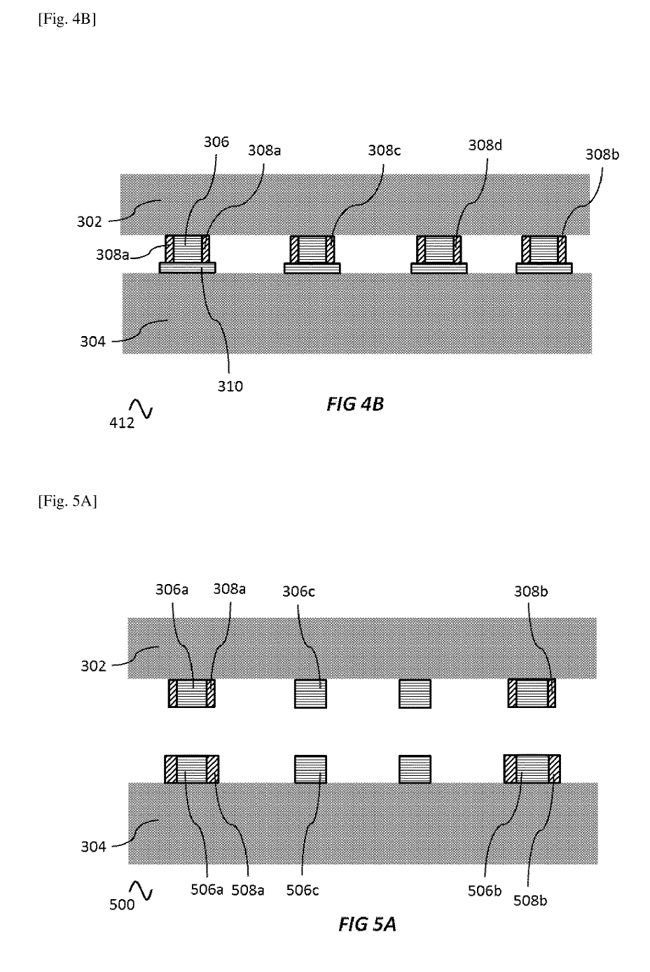

FIGS. 4A and 4B show cross-sectional diagrams illustrating the first and the second substrates prior to and after being bonded in accordance with a second embodiment of the present invention.

Referring to FIG. 4A, the arrangement 400 shows a first substrate 302, an at least one first connection 306a, 306b, 306c, 306d extending from one side of the first substrate 302, a first adhesive material 308a, 308b, 308c, 308d around and along a height of the at least one first connection 306a, 306b, 306c, 306d and at least one UBM portion 310a, 310b, 310c, 310d on the second substrate 304 provided below and away from the first substrate 302.

In the second embodiment, each of the first connections 306c, 306d that are located in the centre of the first substrate 302 is also provided with a first adhesive material 308c, 308d around and along its height. In other words, a first adhesive material 306c, 306d are fabricated around and along the height of the first connection 308c, 308d.

Similarly, the second substrate 304 is provided with UBM portions in its centre. In the second embodiment, the centrelines of the UBM portions 310a, 310b, 310c, 310d are aligned with the centrelines of each of the corresponding first connections 306a, 306b, 306c, 306d on the first substrate 302.

Referring to FIG. 4B, the arrangement 412 shows the first substrate 302, with the first connections 306a, 306b, 306c, 306d extending from one side of the first substrate 302 bonded to the corresponding UBM portions 310a, 310b, 310c, 310d on the second substrate 304 after step 204. During step 204, the first adhesive material 308a, 308b, 308c, 308d and the first connections 306a, 306b, 306c, 306d are bonded to the second substrate 304. In an embodiment, the first adhesive material 308a, 308b, 308c, 308d and the first connections 306a, 306b, 306c, 306d are first bonded together before subsequently bonded to the second substrate 304. Advantageously, the method for bonding a first substrate 302 and a second substrate 304 as presented avoids the formation of the solder bridge 106c. The method of bonding as presented alleviates concerns on formation of the solder bridge 106c, and facilitates higher density of connections with fine pitches.

FIGS. 5A and 5B show cross-sectional diagrams illustrating the first and the second substrates prior to and after being bonded in accordance with a third embodiment of the present invention.

Referring to FIG. 5A, the arrangement 500 shows a first substrate 302, an at least one first connection 306a, 306b extending from one side of the first substrate 302 and a first adhesive material 308a, 308b around and along a height of the at least one first connection 306a, 306b. FIG. 5A also shows a second substrate 304, an at least one second connection 506a, 506b extending from one side of the second substrate 304 and a second adhesive material 508a, 508b around and along a height of the at least one second connection 506a, 506b.

In the third embodiment, there is at least one second connection 506a extending from one side of the second substrate 304. A second adhesive material 508a is fabricated around and along the at least one second connection 506a. The first and the second adhesive material 308a, 508a may be a cylindrical structure around and along the first and the second connection 306a, 506a respectively. In other embodiments, there may be more than one first and second connection 306a, 506a. As shown in FIG. 5A, there are first connections 306a, 306b, 306c extending from the one side of the first substrate 302. The first connections 306a, 306b, 306c may be spaced apart from one another at an equal distance or a different distance. In an embodiment, as shown in FIG. 5A, the first adhesive material 308a, 308b is provided around and along the height of the first connections 306a, 306b that are at the peripheral of the first substrate 302. In other words, the first connections that are located in the centre of the first substrate 302 will not be provided an adhesive material. One such example is first connection 306c.

As shown in FIG. 5A, the second adhesive material 508a, 508b is provided around and along the height of the second connections 506a, 506b that are at the peripheral of the second substrate 304. In other words, the second connections that are located in the centre of the second substrate 304 will not be provided the second adhesive material. One such example is first connection 506c. In an embodiment, as shown in FIG. 5A, the second connections 506a, 506b, 506c are evenly spaced apart on the second substrate 304, wherein centrelines of the second connections 506a, 506b, 506c are aligned with centrelines of the corresponding first connections 306a, 306b, 306c on the first substrate 302.

Referring to FIG. 5B, the arrangement 512 shows the first substrate 302, with the first connections 306a, 306b extending from one side of the first substrate 302 bonded to the second connections 506a, 506b extending from one side of the second substrate 304. The first adhesive material 308a, 308b and the first connections 306a, 306b are bonded to the second adhesive material 508a, 508b and the second connections 506a, 506b. In an embodiment, the first adhesive material 308a, 308b are first bonded to the corresponding first connections 306a, 306b before being bonded to the second substrate 304. The second adhesive material 508a, 508b is also first bonded to the corresponding second connections 506a, 506b before being bonded to the first substrate 302 and the first adhesive material 308a, 308b.

In the third embodiment, the at least one second connections 506a, 506b, 506c can be fabricated using electrochemical plating. The at least one second connections 506a, 506b, 506c can comprise a material selected from but not limited to a group comprising copper, gold, aluminum, tin and indium. The second adhesive material 508a, 508b can be fabricated using an electroless deposition technique (e.g. electroless plating), and the second adhesive thickness is in a range of 100 nm to 2 μm. In other embodiments, the second adhesive thickness may not be limited to the typical range of 100 nm to 2 μm, and can be varied accordingly. The second adhesive material 508a, 508b comprises a material selected from a group comprising tin, indium and a polymer material suitable for fabricating around and along the at least one second connections 506a, 506b. In an embodiment, the material comprised in the second adhesive material 508a may be the same or different from the material comprised in the first adhesive material 308a. In another embodiment, as shown in FIG. 5A, the first adhesive thickness of the first adhesive material 308a, 308b is less than the second adhesive thickness of the second adhesive material 508a, 508b. In other embodiments, the first adhesive thickness of the first adhesive material 308a, 308b may be of the same or greater thickness as the second adhesive thickness of the second adhesive material 508a, 508b.

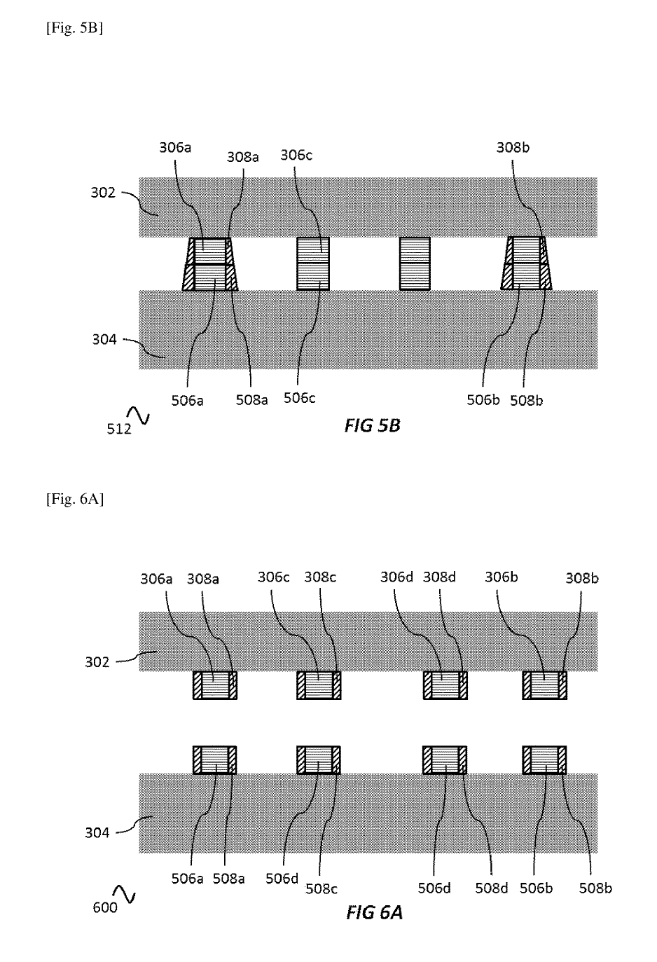

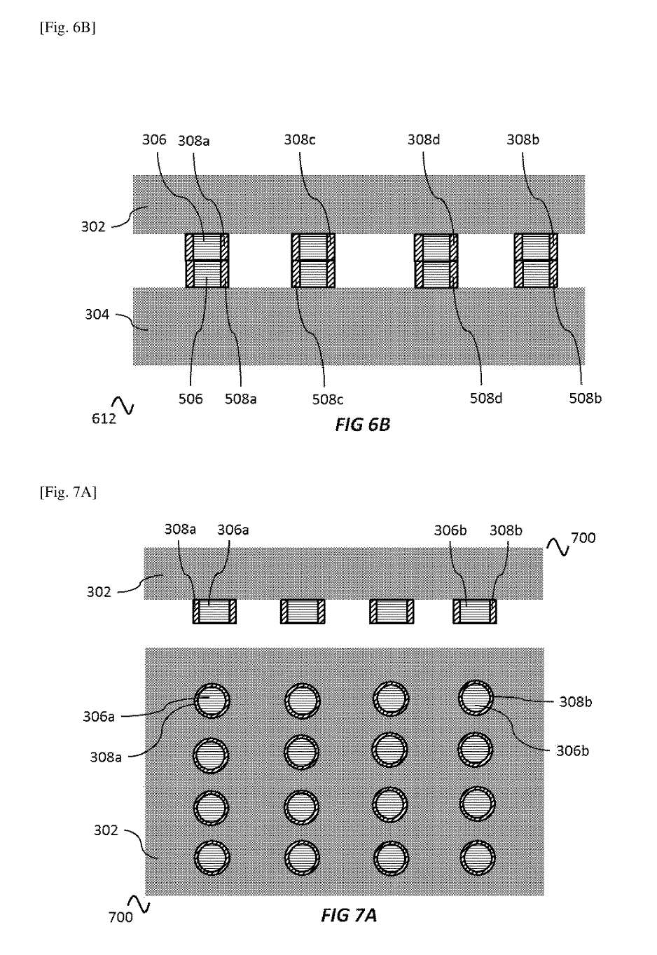

FIGS. 6A and 6B show cross-sectional diagrams illustrating the first and the second substrates prior to and after being bonded in accordance with a fourth embodiment of the present invention.

Referring to FIG. 6A, the arrangement 600 shows a first substrate 302, an at least one first connection 306a, 306b, 306c, 306d extending from one side of the first substrate 302 and a first adhesive material 308a, 308b, 308c, 308d around and along a height of the at least one first connection 306a, 306b, 306c, 306d. FIG. 6A also shows a second substrate 304, an at least one second connection 506a, 506b, 506c, 506d extending from one side of the second substrate 304 and a second adhesive material 508a, 508b, 508c, 508d around and along a height of the at least one second connection 506a, 506b, 506c, 506d.

The first connections in the fourth embodiment are similar to the first connections in the second embodiment. That is, each of the first connections 306c, 306d that are located in the centre of the first substrate 302 is also provided with a first adhesive material 306c, 306d. In the fourth embodiment, the second substrate 304 is provided with the second connections 506c, 506d in the centre. Each of these second connections 506c, 506d that are provided in the centre of the second substrate 304 are provided with a second adhesive material 508c, 508d.

Referring to FIG. 6B, the arrangement 612 shows the first substrate 302, with the first connections 306a, 306b, 306c, 306d extending from one side of the first substrate 302 bonded to the corresponding second connections 506a, 506b, 506c, 506d extending from one side of the second substrate 304. The first adhesive material 308a, 308b, 308c, 308d and the first connections 306a, 306b, 306c, 306d are bonded to the second adhesive material 508a, 508b, 508c, 508d and the second connections 506a, 506b, 506c, 506d. In an embodiment, the first adhesive material 308a, 308b, 308c, 308d are first bonded to the corresponding first connections 306a, 306b, 306c, 306d before being bonded to the second substrate 304. The second adhesive material 508a, 508b, 508c, 508d is also first bonded to the corresponding second connections 506a, 506b, 506c, 506d before being bonded to the first substrate 302 and the first adhesive material 308a, 308b, 308c, 308d.

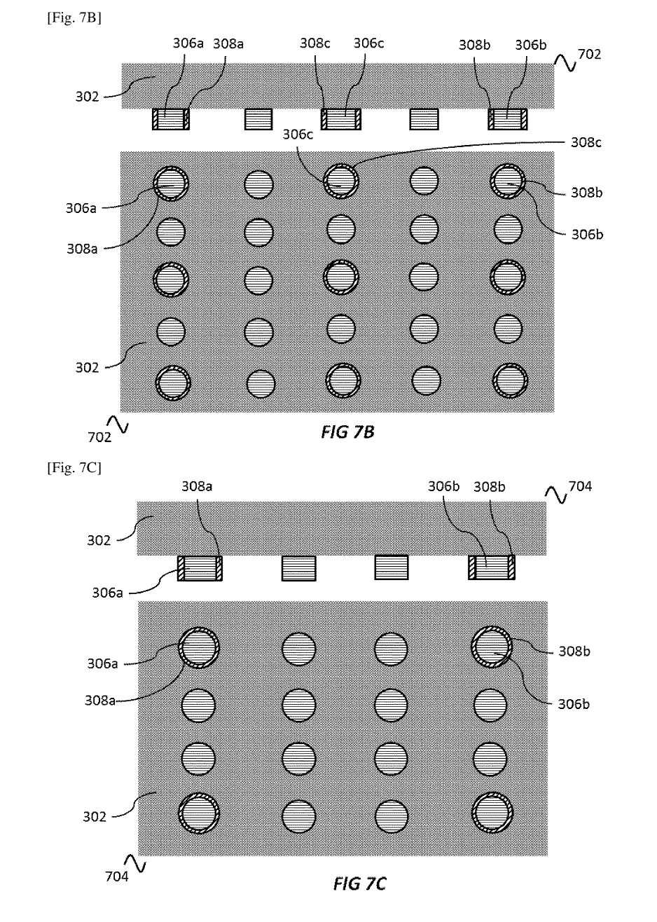

FIGS. 7A to 7C show cross-sectional and plan views of the first and the second substrates in accordance with embodiments of the present invention.

Referring to FIG. 7A, a cross-sectional view and a plan view of an arrangement 700 are shown. The arrangement 700 comprises a first substrate 302, an at least one first connection 306a, 306b extending from one side of the first substrate 302 and a first adhesive material 308a, 308b around and along a height of the at least one first connection 306a, 306b. In an embodiment, as shown in the plan view of FIG. 7A, the first connections 306a, 306b are spaced apart from one another at equal distances in both horizontal and vertical directions. In another embodiment, the first connections 306a, 306b may be spaced apart at different distances in one or two of the horizontal and vertical directions. As shown in FIG. 7A, the first adhesive material 308a, 308b is fabricated around and along the first connections 306a, 306b in step 202 as described in the above. In other words, the first adhesive material is fabricated around and along all of the first connections extending from one side of the first substrate 302. The first adhesive material 308a, 308b may be a cylindrical structure around and along the first connections 306a, 306b. In other embodiments, the arrangement 700 can be used when the distance, otherwise known as pitch, between the adjacent connections are between 10 μm to 20μm. An adhesive thickness of 1 μm is used for the first adhesive material when the pitch is between 10 μm to 20 μm. In yet another embodiment, the arrangement 700 can be used when the pitch are beyond or below the range of 10 μm to 20 μm, with the adhesive thickness of the first adhesive material suitably adjusted.

Referring to FIG. 7B, a cross-sectional view and a plan view of an arrangement 702 is shown. The arrangement 702 comprises a first substrate 302, an at least one first connection 306a, 306b, 306c extending from one side of the first substrate 302 and a first adhesive material 308a, 308b, 308c around and along a height of the at least one first connection 306a, 306b, 306c. In an embodiment, as shown in the plan view of FIG. 7B, the first connections 306a, 306b, 306c are spaced apart from one another at equal distances in both horizontal and vertical directions. In another embodiment, the first connections 306a, 306b, 306c may be spaced apart at different distances in one or two of the horizontal and vertical directions. As shown in FIG. 7B, the first adhesive material 308a, 308b, 308c is fabricated around and along alternate first connections 306a, 306b, 306c in both horizontal and vertical directions in step 202 as described in the above. The first adhesive material 308a, 308b, 308c may be a cylindrical structure around and along the first connections 306a, 306b, 306c. In other embodiments, the arrangement 702 can be used when the pitch between the adjacent connections are between 5 μm to 10 μm. An adhesive thickness of 0.5 μm is used for the first adhesive material when the pitch is between 5 μm to 10 μm. In yet another embodiment, the arrangement 702 can be used when the pitch are beyond or below the range of 5 μm to 10 μm, with the adhesive thickness of the first adhesive material suitably adjusted.

Referring to FIG. 7C, a cross-sectional view and a plan view of an arrangement 704 is shown. The arrangement 704 comprises a first substrate 302, an at least one first connection 306a, 306b extending from one side of the first substrate 302 and a first adhesive material 308a, 308b around and along a height of the at least one first connection 306a, 306b. In an embodiment, as shown in the plan view of FIG. 7C, the first connections 306a, 306b are spaced apart at equal distances in both horizontal and vertical directions. In another embodiment, the first connections may be distributed at different intervals along both horizontal and vertical directions. As shown in FIG. 7C, the first adhesive material 308a, 308b is fabricated around and along the first connections 306a, 306b that are at the corners of the first substrate 302 in step 202 as described in the above. The first adhesive material 308a, 308b may be a cylindrical structure around and along the first connections 306a, 306b. In other embodiments, the arrangement 704 can be used when the pitch between the adjacent connections are less than 5 μm. An adhesive thickness of 0.5 μm is used for the first adhesive material. In yet another embodiment, the arrangement 704 can be used when the pitch are beyond 5 μm, with the adhesive thickness of the first adhesive material adjusted suitably.

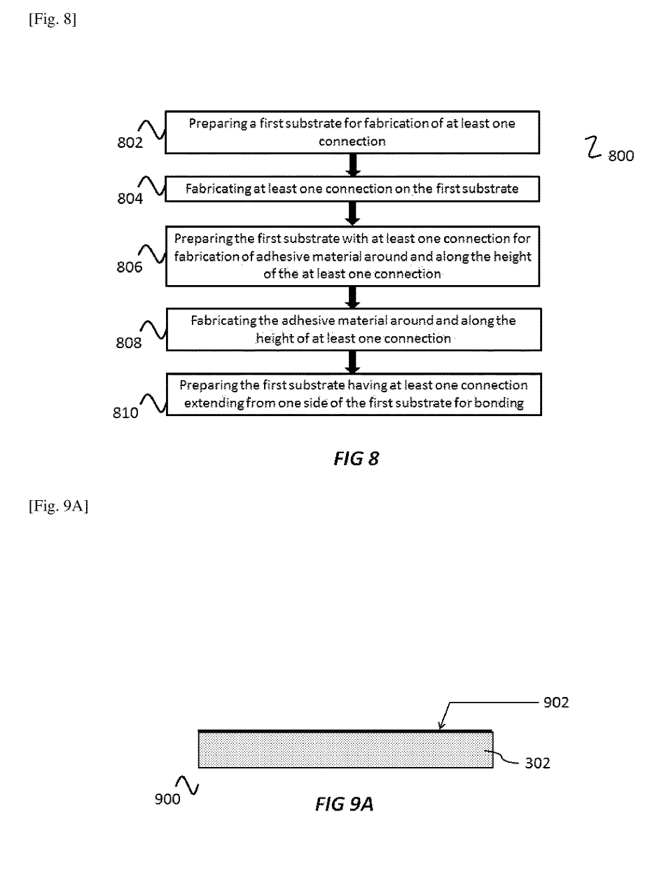

FIG. 8 shows a flowchart illustrating the method for fabricating the first substrate used in the first, second, third and fourth embodiments.

With reference to FIG. 8, the method for fabricating the first substrate 302 used in the first, second, a third and fourth embodiments is illustrated. The method comprises, preparing a first substrate 302 for fabrication of at least one first connection 306a in step 802, fabricating at least one first connection 306a on the first substrate 302 in step 804; preparing the first substrate 302 with at least one first connection 306a for fabrication of adhesive material 308a around and along the height of the at least one first connection 306a in step 806; fabricating the first adhesive material 308a around and along the height of at least one first connection 306a in step 808; and preparing the first substrate 302 having at least one first connection 306a extending from one side of the first substrate 302 for bonding in step 810.

In an embodiment, the step 802 of preparing the first substrate 302 for fabrication of the at least one first connection 306a comprises fabricating a seed layer on the first substrate 302. Examples of the material for the seed layer includes among other things, a material selected from but not limited to a group comprising copper, gold, aluminum, tin and indium. In an embodiment, the step 802 also further comprises fabricating a first photoresist layer on the seed layer and applying a pattern on the first photoresist layer. The first patterned photoresist layer covers the seed layer but includes at least one void which exposes the seed layer beneath to enable formation of the at least one first connection 306a.

In an embodiment, the step 804 of fabricating the at least one first connection 306a on the first substrate 302 comprises electrochemical plating the at least one first connection 306a on the seed layer exposed by the first patterned photoresist layer. Examples of the material for the seed layer includes among other things, a material selected from but not limited to a group comprising copper, gold, aluminum, tin and indium. In an embodiment, the material used in the seed layer is similar to the material used in the at least one first connection 306a.

In a first embodiment, the step 806 of preparing the first substrate 302 with at least one first connection 306a for fabrication of the first adhesive material 308a around and along the height of the at least one first connection 306a comprises removing the first photoresist layer to expose the seed layer fabricated on the first substrate 302. Step 806 further comprises removing the seed layer fabricated on the first substrate 302 to expose the first substrate 302 and the at least one first connection 306a extending from the first substrate 302. In an embodiment, after step 806, the step 808 of fabricating the first adhesive material 308a around and along the height of at least one first connection 306a comprises electroless plating the first adhesive material 308a on the at least one first connection 306a. In the embodiment, the step 806 comprises immersing the at least one first connection 306a fully in a chemical solution for electroless plating to occur. The immersion process requires duration of few minutes, and a range of adhesive thickness of the first adhesive material 308a can be fabricated on the at least one first connection 306a. In another embodiment, the step 810 of preparing the first substrate 302 having at least one first connection 306a extending from one side of the first substrate 302 for bonding comprises fabricating a second photoresist layer on the first substrate 302 to a height that is above and beyond the height of the at least one first connection 306a and the adhesive material 308a on the at least one first connection 306a. The second photoresist layer acts as a dummy film to support the at least one first connection 306a during a surface planarization process. The surface planarization process is a process of smoothing surfaces with a combination of chemical and mechanical forces. The surface planarization process strips away a layer of the dummy film, the at least one first connection 306a and the first adhesive material 308a to expose the at least one first connection 306a, and form the adhesive material 308a around and along the height of the at least one first connection 306a. In an embodiment, the step 810 further comprises removing the dummy film, to form the first substrate 302, with the at least one first connection 306a extending from the first substrate 302, and the first adhesive material 308a around and along the height of at least one first connection 306a.

In a second embodiment, the step 806 of preparing the first substrate 302 with at least one first connection 306a for fabrication of the first adhesive material 308a around and along the height of the at least one first connection 306a comprises removing the photoresist layer to expose the seed layer fabricated on the first substrate 302. Step 806 also comprises removing the seed layer fabricated on the first substrate 302 to expose the first substrate 302 and the at least one first connection 306a extending from the first substrate 302. Step 806 further comprises fabricating a second photoresist layer on the exposed seed layer and the least one first connection 306a. The second photoresist layer is fabricated to a height above and beyond the height of the at least one first connection 306a. The second photoresist layer is subsequently patterned. In embodiments of the present invention, the patterning comprises removing a thickness of the second photoresist layer around and along the height of the at least one first connection 306a to form exposed at least one first connection 306a. In an embodiment, the patterning may include removing the second photoresist layer around and along the at least one first connection 306a that are at the corner of the first substrate 302. In yet another embodiment, the patterning may include removing the second photoresist layer around and along alternate rows and columns of the at least one first connection 306a. In an embodiment, after step 806, the step 808 of fabricating the first adhesive material 308a on the at least one first connection 306a comprises electroless plating the first adhesive material 308a on the exposed at least first connection 306a. In an embodiment, the step 806 comprises immersing the at least one first connection 306a fully in a chemical solution for electroless plating to occur. The first adhesive material 308a will be fabricated on the exposed at least first connection 306a. The immersion process requires duration of few minutes, and a range of adhesive thickness of the first adhesive material 308a can be fabricated on the exposed at least one first connection 306a. In an embodiment, the step 810 comprises a surface planarization process. The surface planarization process is performed after fabricating the first adhesive material 308a on the exposed at least first connection 306a. The surface planarization process strips away a thickness of the second photoresist layer, the at least one first connection 306a and the first adhesive material 308a to expose the at least one first connection 306a. In an embodiment, the step 810 further comprises removing the dummy film, to form the first substrate 302, with the at least one first connection 306a extending from the first substrate 302, and the first adhesive material 308a around and along the height of at least one first connection 306a.

In embodiments of the invention, the first adhesive material 308a and the at least one first connection 306a are bonded to the second substrate in a step similar to step 204.

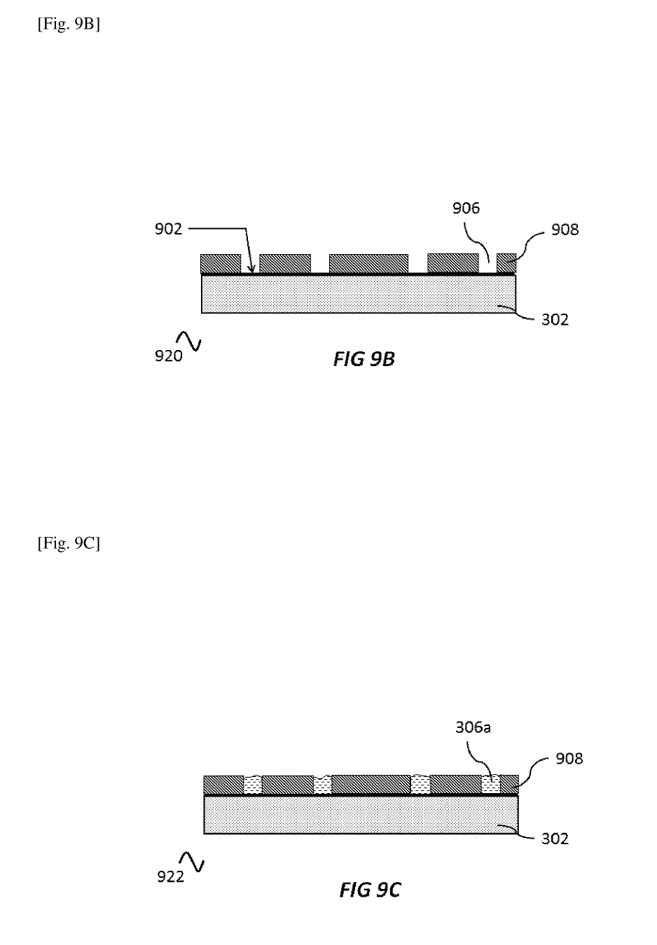

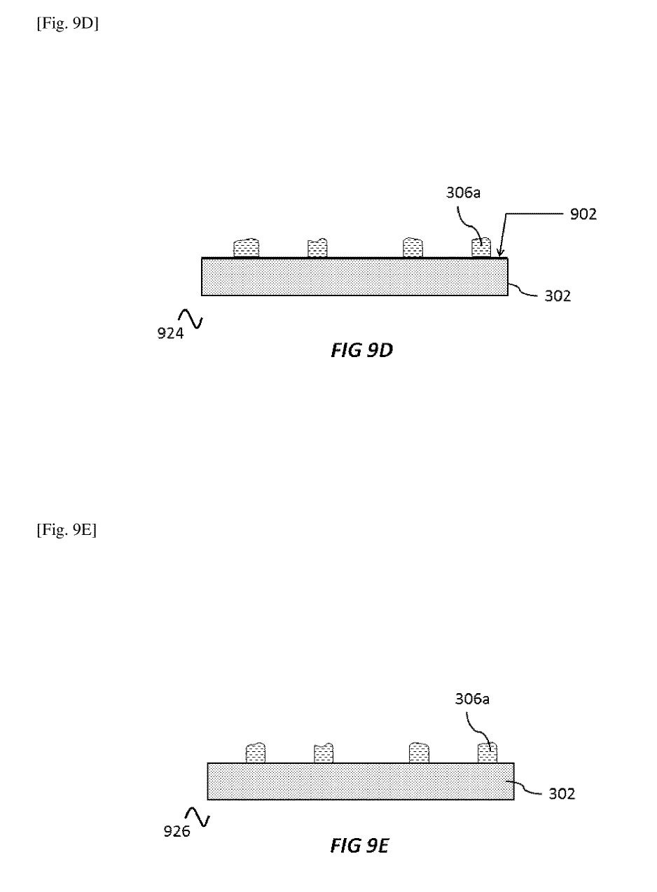

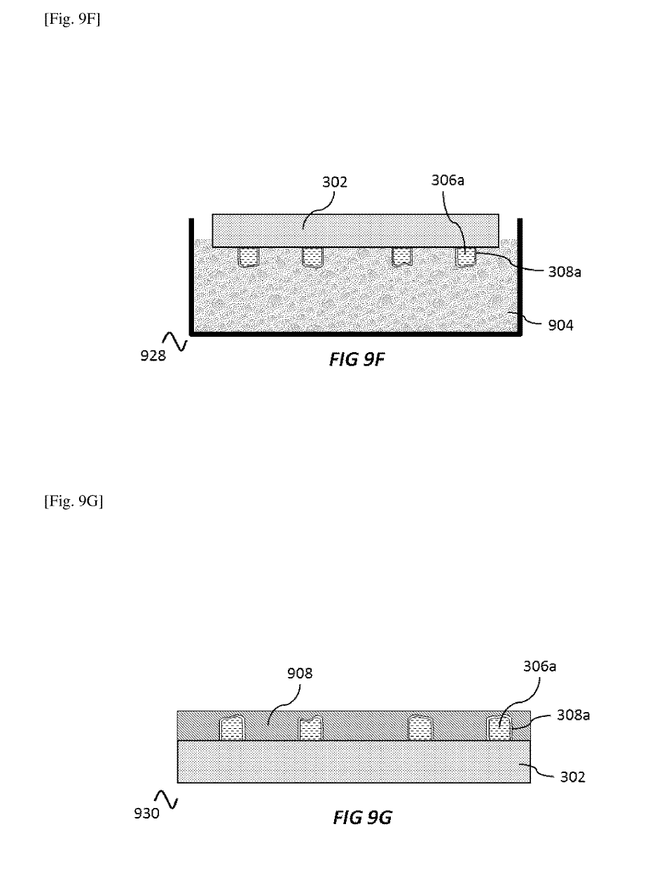

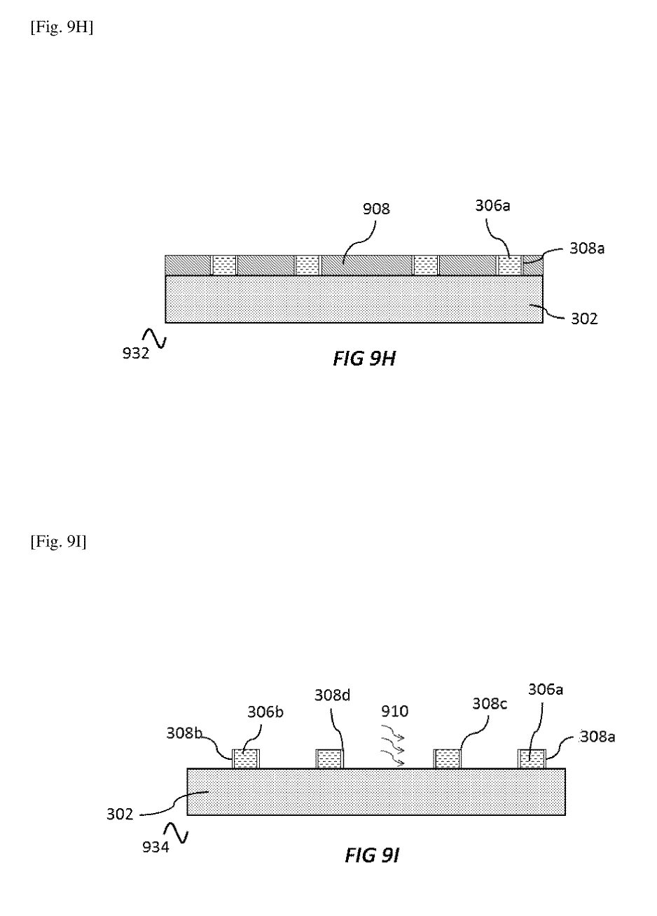

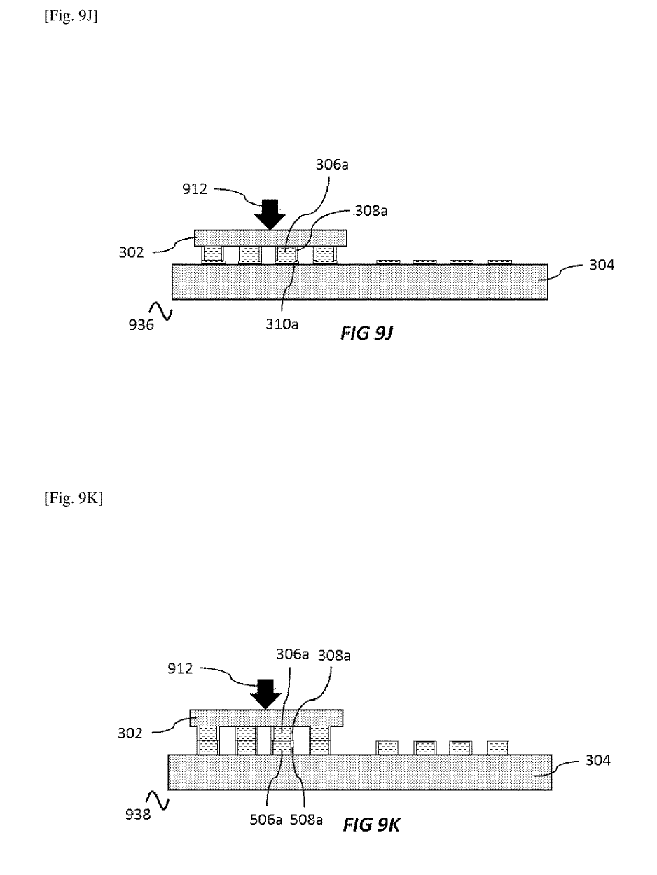

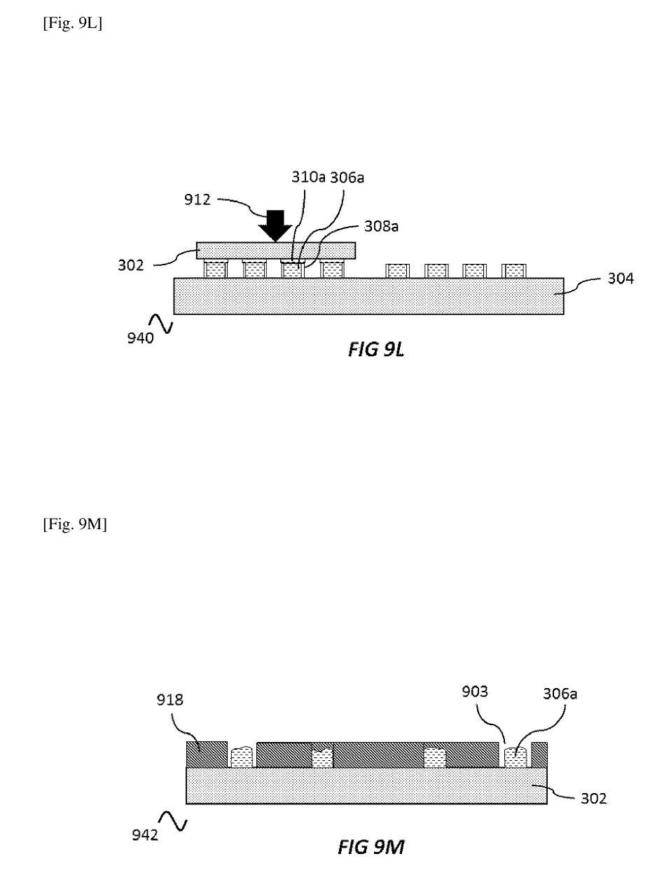

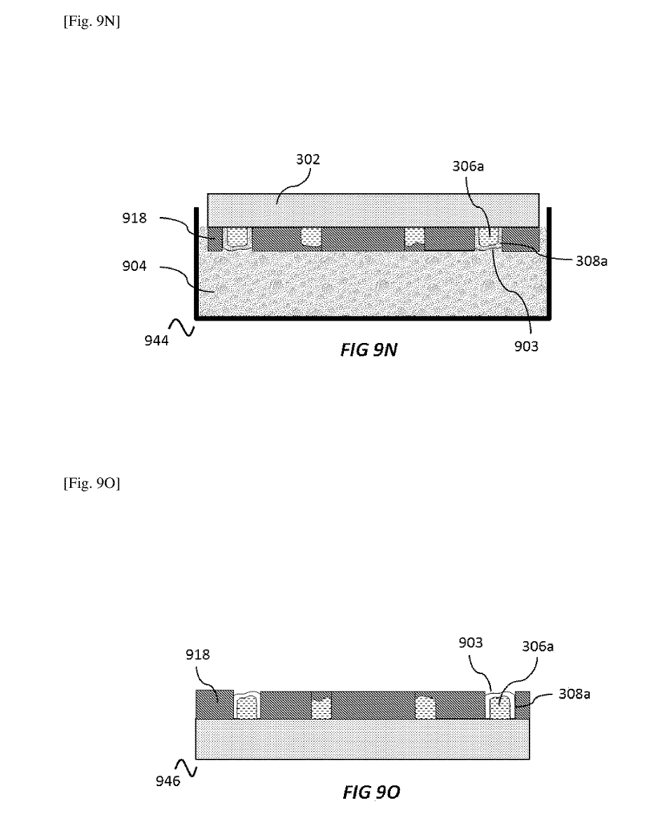

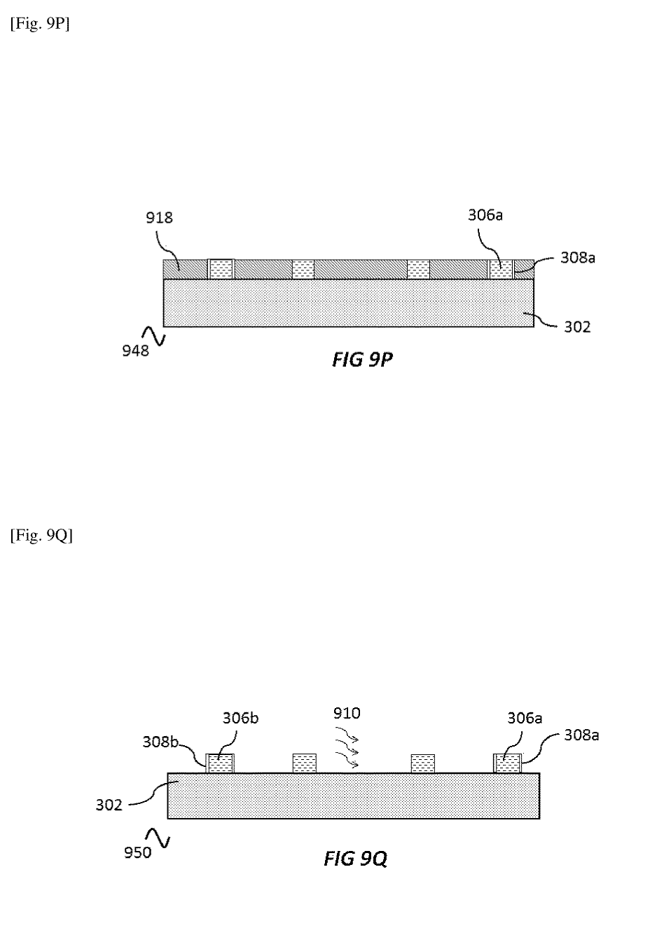

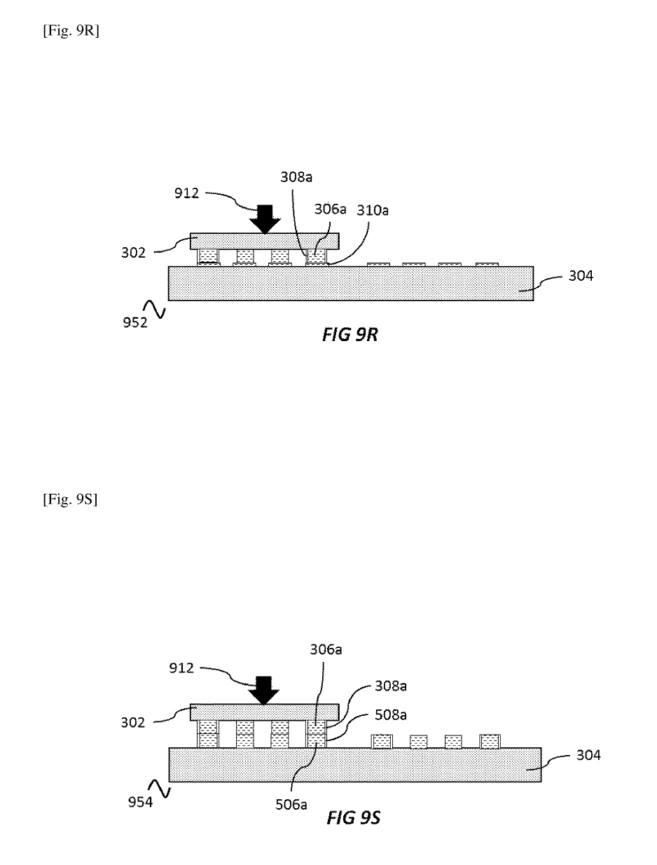

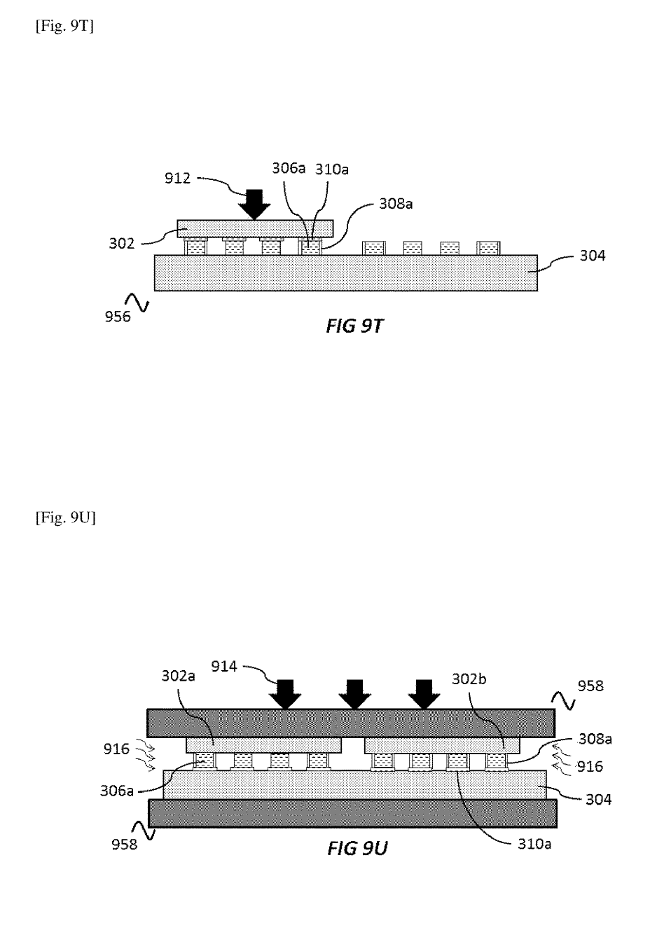

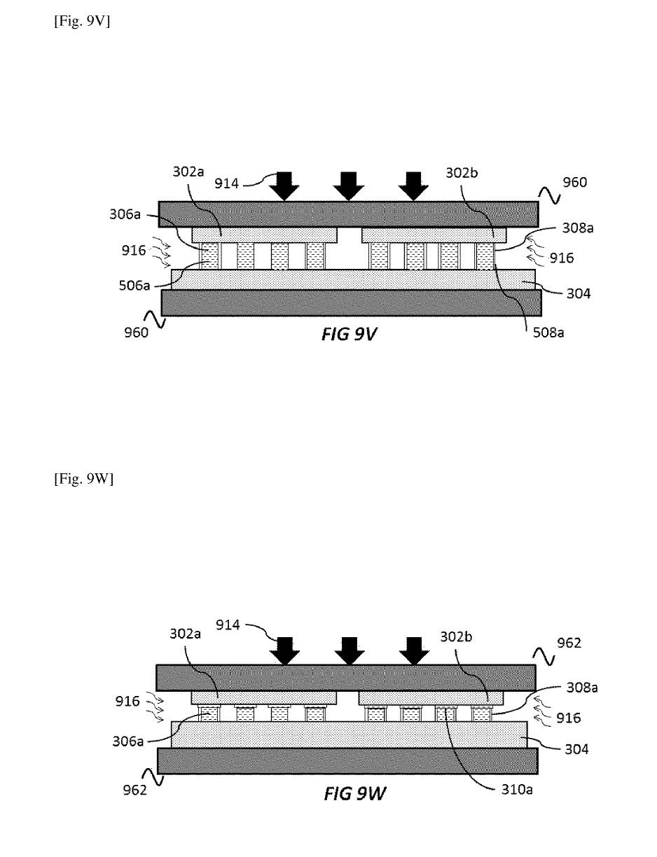

FIGS. 9A to 9W show cross-sectional diagrams illustrating embodiments of the method described in FIG. 8.

Referring to FIG. 9A, a metal material 902 is provided on the substrate 302. The metal material 902 is planar to the substrate 302. Examples of the metal material 902, includes among other things, a material selected from but not limited to a group comprising copper, gold, aluminum, tin and indium. The metal material 902 is so provided on the substrate 302 to serve as a seed layer to enable formation of the at least one connection structure 306 on the substrate 302 as described in step 802.

Referring to FIG. 9B, a first patterned photoresist layer 908 formed in the step 802 is provided on the metal material 902. The first patterned photoresist layer 908 covers the metal material 902 and includes at least one void 906 that exposes the metal material 902 beneath to provide for the formation of the at least one first connection 306a.

Referring to FIG. 9C, the at least one connection 306a is provided within the at least one void 906 in the first patterned photoresist layer 908. In an embodiment, the at least one connection 306a is formed in step 804 through electrochemical plating. The at least one connection 306a is deposited on the metal material 902 and occupies the whole of the at least one void 906. Due to the nature of the electrochemical plating process, the crown of the at least one connection 306a may be uneven.

Referring to FIG. 9D, the first patterned photoresist layer 908 is removed as described in step 806 to expose portions of the metal material 902. The resulting structure includes the at least one connection 306a which will also be exposed.

Referring to FIG. 9E, the metal material 902 is removed as described in step 806 to expose the substrate 302 and portions of the at least one connection 306a. After removal of metal material 902 there are various ways to fabricate the adhesive material 308a. One way is to provide a second patterned photoresist layer 918 on the substrate 302; more information will be described in FIG. 9M below.

Another way of fabricating the adhesive material 308a is shown in FIG. 9F. Referring to FIG. 9F, the at least one connection 306a is fully immersed in the chemical solution 904 in a manner described in step 808, and the adhesive material 308a is provided on the at least one connection 306a that is exposed to the chemical solution 904.

Following FIG. 9F, FIG. 9G shows a second photoresist layer 908 provided on the substrate 302. The second photoresist layer 908 envelops the at least one connection 306a, with the adhesive material 308a to support the at least one connection 306a during the surface planarization process as described in step 810.

Referring to FIG. 9H, the surface planarized second photoresist layer 908, with the at least one connection 306a and the adhesive material 308a on the substrate 302 is provided. FIG. 9H shows the substrate 302 after the process of surface planarization as described in step 810 has been performed, where a thickness of the second photoresist layer 908 is stripped away in step 806 together with a thickness of the at least one connection 306a and the adhesive material 308a to expose the at least one connection 306a.

Referring to FIG. 9I, the layer of the second photoresist layer 908 as shown in FIG. 9H is removed in step 810. Hydrogen plasma 910 is used to remove impurities on the exposed surfaces of the at least one first connection 306a, 306b, 306c, 306d. In other words, the hydrogen plasma 910 is used to remove impurities on surfaces of the at least one first connection 306a, 306b, 306c, 306d that are not covered by the adhesive material 308a, 308b, 308c, 308d.

Thus, FIGS. 9F-9I shows one method of fabricating the adhesive material 308a and preparing the first substrate 302 for bonding to the second substrate 304. The following FIGS. 9J-9L show how the first substrate 302 (as prepared by the process shown in FIGS. 9F-9I) may be bonded to various arrangements of the second substrate 304 using a flip-chip technique described in step 204.

FIG. 9J provides one example of bonding the first substrate 302 and the second substrate 304. A bonding force 912 is provided on the first substrate 302 to bond the at least one first connection 306a, the first adhesive material 308a and the second substrate 304 as described in step 204. In FIG. 9J, the first substrate 302 comprises at least one first connection 306a and the second substrate 304 comprises at least one UBM portion 310a.

FIG. 9K provides another example of bonding the first substrate 302 and the second substrate 304. A bonding force 912 is provided on the first substrate 302 to bond the at least one first connection 306a, the first adhesive material 308a and the second substrate 304 as described in step 204. In FIG. 9K, the second substrate 304 comprises at least one second connection 506a. The second adhesive material 508a is provided around and along the height of the at least one second connection 506a.

FIG. 9L provides yet another example of bonding the first substrate 302 and the second substrate 304. A bonding force 912 is provided on the substrate 302 to bond the first substrate and the second substrate 304 in a step similar to step 204. In FIG. 9L, the first substrate 302 comprises at least one UBM portion 310a and the second substrate 304 comprises at least one connection 306a extending from one side of the second substrate 304. The adhesive material 308a is provided around and along the height of the connection 306a.

As mentioned in the above, there are various ways to fabricate the adhesive material 308a on the at least one connection 306a of the substrate 302 shown in FIG. 9E. FIGS. 9M-9Q describe an alternative method different from that shown in FIGS. 9F-9I.

Referring to FIG. 9M, a second patterned photoresist layer 918 is provided on the substrate 302 shown in FIG. 9E. In other words, it is possible to provide the second patterned photoresist layer 918 without having to perform the steps described in FIGS. 9F-9I. In FIG. 9M, a thickness around and along the height of the at least one connection 306a is removed to form a gap 903. The gap 903 is provided to expose the at least one connection 306a for fabrication of the adhesive material 308a. In one embodiment, the second photoresist layer 918 may be patterned to expose only at least one connection 306a at the corner of the substrate 302. Alternatively, the second photoresist layer 918 may be patterned to provide gap 903 around and along alternate rows and columns of the at least one first connection 306a.

Following FIG. 9M, FIG. 9N shows the substrate 302 provided in a chemical solution 904 for fabrication of the adhesive material 308a as described in step 808. The at least one connection 306a is fully immersed in the chemical solution 904, and the adhesive material 308a is provided on the at least one connection 306a that are exposed to the chemical solution 904. In other words, the adhesive material 308a is provided on the at least one connection 306a positioned within the gap 903 within the second patterned photoresist layer 918. That is, the adhesive material 308a is not deposited on the at least one connection 306a that is enveloped within the second patterned photoresist layer 918.

FIG. 9Q shows the second photoresist layer 918 provided around the at least one connection 306a, and the adhesive material 308a on the at least one connection 306a located at the peripheral of the substrate 302. The second photoresist layer 918 serves to support the at least one connection 306a during the surface planarization process as described in step 810.

FIG. 9P show the substrate 302 after surface planarization of step 810 has been performed, where a thickness of the second photoresist layer 918 is stripped away together with a thickness of the at least one connection 306a and the adhesive material 308a to expose the at least one connection 306a.

Referring to FIG. 9Q, the second photoresist layer 918 shown in FIG. 9P is removed as described in step 810. Hydrogen plasma 910 is subsequently used to remove impurities on the exposed surfaces of the at least one first connection 306a, 306b to prepare for bonding the substrate 302, the first adhesive material 308a, 308b and the second substrate 304.

Thus, FIGS. 9M-9Q show an alternate method of fabricating the adhesive material 308a and preparing the first substrate 302 for bonding to the second substrate 304. The following FIGS. 9R-9T show how the first substrate 302 (as prepared by the process shown in FIGS. 9M-9Q) may be bonded to various arrangements of the second substrate 304 using a flip-chip technique described in step 204.

FIG. 9R provides one example of bonding the first substrate 302 and the second substrate 304. A bonding force 912 is provided on the first substrate 302 to bond the at least one first connection 306a, the first adhesive material 308a and the second substrate 304 as described in step 204. In FIG. 9R, the first substrate 302 comprises at least one first connection 306a and the second substrate 304 comprises at least one UBM portion 310a. The first adhesive material 308a is provided around and along the height of the at least one first connections 306a that are at the peripheral of the first substrate 302.

FIG. 9S provides another example of bonding the first substrate 302 and the second substrate 304. A bonding force 912 is provided on the substrate 302 to bond the first substrate and the second substrate 304 in a step similar to step 204. The first adhesive material 308a and the second adhesive material 508a are provided respectively around and along the height of the at least one first and second connections 306a, 506a that are at the peripheral of the first and second substrates 302, 304.

FIG. 9T provides yet example of bonding the first substrate 302 and the second substrate 304. In FIG. 9T, the first substrate 302 comprises at least one UBM portion 310a and the second substrate 304 comprises at least one connection 306a extending from one side of the second substrate 304. The adhesive material 308a is provided around and along the height of the connection 306a. A bonding force 912 is provided on the substrate 302 to bond the first substrate and the second substrate 304 in a step similar to step 204.

FIGS. 9J-9L and FIGS. 9R-9T show the first substrate 302 being bonded to various arrangements of the second substrate 304 using a flip-chip technique described in step 204. The assembly of at least one first substrate 302 and second substrate 304 shown in FIGS. 9J-9L and FIGS. 9R-9T is subsequently placed in a global wafer bonder, wherein the step 204 of bonding the first connection, the first adhesive material and the single second substrate is performed using a global bonder technique. FIGS. 9U-9W show the various arrangements of the first and second substrate 302,304 being bonded in the global wafer bonder.

FIG. 9U shows a first example of the first and second substrate 302a, 302b, 304 being bonded in the global wafer bonder. A global bonding force 914 is provided on the first substrates 302a, 302b to bond the first substrates 302a, 302b with the single common second substrate 304. The at least one first connection 306a extending from the first substrates 302a, 302b, the first adhesive material 308a and the UBM portions 310a on the single common second substrate 304 are being bonded. Formic acid gas 916 is channeled through the at least one connection 306a to remove impurities present on the exposed surfaces of the at least one connection 306a.

FIG. 9V shows a second example of the first and second substrate 302a, 302b, 304 being bonded in the global wafer bonder. A global bonding force 914 is provided on the first substrates 302a, 302b to bond the first substrates 302a, 302b with the single common second substrate 304. The at least one first connection 306a, the at least one second connection 506a extending from the first and second substrates 302a, 302b, 304 and the first and the second adhesive material 308a, 508a are being bonded. Formic acid gas 916 is channeled through the at least one connection 306a, 506a to remove impurities present on the exposed surfaces of the at least one first and second connection 306a, 506a.

FIG. 9W shows a third example of the first and second substrate 302a, 302b, 304 being bonded in the global wafer bonder. Similar to FIG. 9U and FIG. 9V, a global bonding force 914 is provided on the first substrates 302a, 302b to bond the first substrates 302a, 302b with the single common second substrate 304. Formic acid gas 916 is channeled through the at least one connection 306a to remove impurities on surfaces that may not be adequately enveloped by the adhesive material 308a.

Thus it can be seen that a method of bonding the first substrate and the second substrate in accordance with the present embodiments have the advantages of improved alignment, higher mechanical strength, better electrical conductivity, greater device reliability and higher density of connections with fine pitches. While exemplary embodiments have been presented in the foregoing detailed description of the invention, it should be appreciated that a vast number of variations exist.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of elements and method of operation described in an exemplary embodiment without departing from the scope of the invention as set forth in the appended claims.

1. A method for bonding a first substrate and a second substrate, the first substrate having at least one first connection extending from one side of the first substrate and the second substrate including at least one under bump metallization (UBM) portion wherein the at least one UBM portion has a broader width across the second substrate than a width of the first connection across the first substrate, the method comprising:
fabricating a first adhesive material only around and along a height of the at least one first connection;
aligning centerlines of the at least one first connection and a corresponding one of the at least one UBM portion of the second substrate and bonding the at least one first connection, the first adhesive material, and the corresponding one of the at least one UBM portion of the second substrate using a flip chip bonding technique; and
thereafter permanently bonding the at least one first connection, the first adhesive material, and the corresponding one of the at least one UBM portion of the second substrate using a global bonder technique.

2. (canceled)

3. A method for bonding a first substrate and a second substrate, the first substrate having at least one first connection extending from one side of the first substrate and the second substrate having at least one second connection extending from one side of the second substrate, the method comprising:
fabricating a first adhesive material only around and along a height of the at least one first connection;
fabricating a second adhesive material only around and along a height of the at least one second connection;
aligning centerlines of the at least one first connection and a corresponding one of the at least one second connection and bonding the at least one first connection, the first adhesive material, the corresponding one of the at least one second connection, and the second adhesive material using a flip chip technique; and
thereafter permanently bonding the at least one first connection, the first adhesive material, the corresponding one of the at least one second connection of the second substrate, and the second adhesive material using a global bonder technique.

4. (canceled)

5. A method according to claim 1, further comprising:
fabricating the at least one first connection on one side of the first substrate.

6. The method according to claim 1, wherein the step of fabricating the first adhesive material comprises:
fabricating a first adhesive thickness of the first adhesive material, the first adhesive thickness being substantially uniform along the height of the at least one first connection.

7. A method according to claim 3, further comprising:
fabricating the at least one second connection on one side of the second substrate.

8. The method according to claim 3, wherein the step of fabricating the second adhesive material comprises:
fabricating a second adhesive thickness of the second adhesive material, the second adhesive thickness being substantially uniform along the height of the second connection.

9. The method according to claim 6, wherein the first adhesive thickness is in a range of 100 nm to 2 μm.

10. The method according to claim 8, wherein the second adhesive thickness is in a range of 100 nm to 2 μm.

11. The method according to claim 1, wherein the at least one first connection comprises a material selected from a group comprising copper, gold, aluminum, tin and indium.

12. The method according to claim 3, wherein the at least one second connection comprises a material selected from a group comprising copper, gold, aluminum, tin and indium.

13. The method according to claim 1, wherein the first adhesive material comprises a material selected from a group comprising tin, indium and a polymer material suitable for fabricating around and along the at least one first connection.

14. The method according to claim 3, wherein the second adhesive material comprises a material selected from a group comprising tin, indium and a polymer material suitable for fabricating around and along the at least one second connection.

15. The method according to claim 2, wherein the at least one UBM portion comprises a material selected from a group comprising copper, gold, aluminum, tin and indium.

16. The method according to claim 3, wherein the step of fabricating the first adhesive material and the second adhesive material is performed using an electroless deposition technique.

17. The method according to claim 14, wherein the material comprised in the second adhesive material is the same as a material comprised in the first adhesive material.

18. (canceled)

19. (canceled)

20. A method according to claim 1, wherein the step of aligning and bonding the at least one first connection, the first adhesive material, and the corresponding one of the at least one UBM portion of the second substrate using the flip chip technique comprises heating the first and the second substrates to a melting temperature of the first adhesive material when the first adhesive material is a metal.

21. A method according to claim 1, wherein the step of aligning and bonding the at least one first connection, the first adhesive material, and the corresponding one of the at least one UBM portion of the second substrate using the flip chip technique comprises heating the first and the second substrates to a lowest melt-viscosity temperature after B stage when the first adhesive material is a thermoset polymer.

22. A method according to claim 1, wherein the step of aligning and bonding the at least one first connection, the first adhesive material, and the corresponding one of the at least one UBM portion of the second substrate using the flip chip technique comprises heating the first and the second substrates to a low melt-viscosity temperature of less than 200 degree Celsius when the first adhesive material is a thermoplastic polymer.

23. A method according to claim 3, wherein the step of aligning and bonding the at least one first connection, the first adhesive material, the corresponding one of the at least one second connection, and the second adhesive material comprises heating the first and the second substrates to a melting temperature of the first and second adhesive materials when the first and second adhesive materials are metals.

24. A method according to claim 3, wherein the step of aligning and bonding the at least one first connection, the first adhesive material, the corresponding one of the at least one second connection, and the second adhesive material comprises heating the first and the second substrates to a lowest melt-viscosity temperature after B stage when the first and second adhesive materials are a thermoset polymer.

25. A method according to claim 3, wherein the step of aligning and bonding the at least one first connection, the first adhesive material, the corresponding one of the at least one second connection, and the second adhesive material comprises heating the first and the second substrates to a low melt-viscosity temperature of less than 200 degree Celsius when the first and second adhesive materials are a thermoplastic polymer.

26. A method according to claim 3, wherein a width of the at least one first connection across the first substrate is substantially equivalent to a width of the at least one second connection across the second substrate.
